(19) United States
(12) Patent Application Publication
(10) Pub. No.: US 2016/0277040 A1
(43) Pub. Date: Sep. 22, 2016

(54) COMMUNICATION METHOD AND COMMUNICATION APPARATUS

(71) Applicant: KYOCERA CORPORATION, Kyoto (JP)

(72) Inventors: Fangwei TONG, Tokyo (JP); Chiharu YAMAZAKI, Tokyo (JP)

(73) Assignee: KYOCERA CORPORATION, Kyoto (JP)

(21) Appl. No.: 15/169,252

(22) Filed: May 31, 2016

Related U.S. Application Data
(63) Continuation of application No. PCT/JP2014/081305, filed on Nov. 27, 2014.

(30) Foreign Application Priority Data
Dec. 6, 2013 (JP) 2013-252961

(51) Int. Cl. H03M 13/35; H04B 7/04; H04W 8/02; H04L 1/00; H04W 76/04

(52) U.S. Cl. CPC H03M 13/353; H04L 1/0041; H04W 76/046; H04W 8/02; H04B 7/0404; H04W 92/20

(57) ABSTRACT

A transmitting apparatus includes: a grouping unit (11A) configured to divide the information bit sequence to generate multiple information bit groups having different degrees of importance; an encoding unit (12A) configured to individually encode each of the multiple information bit groups at a coding rates set according to a corresponding degree of importance while maintaining a total coding rate for the multiple information bit groups to be the target coding rate; and a coupling unit (13A) configured to couple multiple encoded bit groups obtained by individually encoding the multiple information bit groups, to generate the encoded bit sequence.

### TECHNICAL FIELD

The present disclosure relates to a communication method and a communication apparatus in a communication system using error correction techniques.

### BACKGROUND ART

In a communication system, error correction techniques are used to correct a transmission error of information bit sequences. For example, in Long Term Evolution (LTE) whose specification has been established in the 3rd Generation Partnership Project (3GPP), turbo codes or the like are used as error correction codes (see Non Patent Literature 1).

In such error correction techniques, a transmitting side communication apparatus performs error correction encoding (hereinafter, referred to simply as “encoding”) by adding a redundancy (redundant bits) to an information bit sequence, and transmits the encoded bit sequence obtained by the encoding. A receiving side communication apparatus performs error correction decoding (hereinafter, referred to simply as “decoding”) by detecting and correcting the transmission error of encoded bit sequence using the redundancy, and obtains an original information bit sequence.

A ratio (N/K) of the number (N) of bits of an information bit sequence to the number (K) of bits of an encoded bit sequence is referred to as a “coding rate.” Generally, in the case of the same encoding method, as the coding rate decreases, an error correction performance is improved, but the redundancy, that is, an overhead increases. Meanwhile, as the coding rate increases, the overhead decreases, but the error correction performance decreases.

### CITATION LIST

### Non Patent Literature

Non Patent Literature 1: 3GPP technical specification “TS 36.212 V11.3.0,” June, 2013

### SUMMARY

By the way, the information bit sequence includes bits having a high degree of importance and bits having a low degree of importance. For example, a transmission error of a most significant bit (MSB) of the information bit sequence is larger in an error occurring as a result than a transmission error of a least significant bit (LSB), and thus the MSB is more important than the LSB.

However, in the above-mentioned error correction technique, since the encoded bit sequence is obtained by encoding the entire information bit sequence at a target coding rate, it is hard to set an error correction performance for bits having a high degree of importance to be different from an error correction performance for bits having a low degree of importance.

In this regard, it is an object of the present disclosure to provide a communication method and a communication apparatus, which are capable of setting an error correction performance for bits having a high degree of importance to be different from an error correction performance for bits having a low degree of importance while suppressing an increase in an overhead.

A communication method according to a first aspect is a method in a communication apparatus for transmitting an encoded bit sequence obtained by encoding an information bit sequence at a target coding rate. The communication method includes: a grouping step of dividing the information bit sequence to generate multiple information bit groups having different degrees of importance; an encoding step of individually encoding each of the multiple information bit groups at a coding rates set according to a corresponding degree of importance while maintaining a total coding rate for the multiple information bit groups to be the target coding rate; and a coupling step of coupling multiple encoded bit groups obtained by individually encoding the multiple information bit groups, to generate the encoded bit sequence. In the encoding step, a coding rate applied to an information bit group having a high degree of importance is set to be lower than a coding rate applied to an information bit group having a low degree of importance.

A communication method according to a second aspect is a method in a communication apparatus for receiving an encoded bit sequence obtained by encoding an information bit sequence at a target coding rate. The communication method includes: a classifying step of dividing the encoded bit sequence to generate multiple encoded bit groups having different coding rates; a step of decoding each of the multiple encoded bit groups; a coupling step of coupling multiple information bit groups having different degrees of importance obtained by decoding the multiple encoded bit groups, to generate the information bit sequence. Each of the multiple information bit groups is individually encoded at a coding rates set according to a corresponding degree of importance while maintaining a total coding rate for the multiple information bit groups to be the target coding rate. A coding rate of an information bit group having a high degree of importance is set to be lower than a coding rate of an information bit group having a low degree of importance.

A communication apparatus according to a third aspect transmits an encoded bit sequence obtained by encoding an information bit sequence at a target coding rate. The communication apparatus includes a processor. The processor is configured to execute: a grouping process of dividing the information bit sequence to generate multiple information bit groups having different degrees of importance; an encoding process of individually encoding each of the multiple information bit groups at a coding rates set according to a corresponding degree of importance while maintaining a total coding rate for the multiple information bit groups to be the target coding rate; and a coupling process of coupling multiple encoded bit groups obtained by individually encoding the multiple information bit groups, to generate the encoded bit sequence. In the encoding process, the processor sets a coding rate applied to an information bit group having a high degree of importance to be lower than a coding rate applied to an information bit group having a low degree of importance.

A communication apparatus according to a fourth aspect receives an encoded bit sequence obtained by encoding an information bit sequence at a target coding rate. The communication apparatus includes a processor. The processor is configured to execute: a classifying process of dividing the encoded bit sequence to generate multiple encoded bit groups having different coding rates; a process of decoding each of the multiple encoded bit groups; a coupling process of coupling multiple information bit groups having different degrees of importance obtained by decoding the multiple encoded bit groups, to generate the information bit sequence. Each of the multiple information bit groups is individually encoded at a coding rates set according to a corresponding degree of importance while maintaining a total coding rate for the multiple information bit groups to be the target coding rate. A coding rate of an information bit group having a high degree of importance is set to be lower than a coding rate of an information bit group having a low degree of importance.

### BRIEF DESCRIPTION OF DRAWINGS

FIG. 1 is a configuration diagram illustrating an LTE system according to first and second embodiments.

FIG. 2 is a block diagram illustrating a UE according to the first and second embodiments.

FIG. 3 is a block diagram illustrating an eNB according to the first and second embodiments.

FIG. 4 is a protocol stack diagram of a radio interface in an LTE system.

FIG. 5 is a block diagram illustrating a transmitting side apparatus according to the first embodiment.

FIG. 6 is a diagram illustrating an operation of the transmitting side apparatus according to the first embodiment.

FIG. 7 is a block diagram illustrating a receiving side apparatus according to the first embodiment.

FIG. 8 is a diagram illustrating an operation of the receiving side apparatus according to the first embodiment.

FIG. 9 is a diagram illustrating a third modification of the first embodiment.

FIG. 10 is a block diagram illustrating a transmitting side apparatus according to the second embodiment.

FIG. 11 is a first diagram illustrating an operation of a transmitting side apparatus according to the second embodiment.

FIG. 12 is a second diagram illustrating an operation of a transmitting side apparatus according to the second embodiment.

FIG. 13 is a block diagram illustrating a receiving side apparatus according to the second embodiment.

FIG. 14 is a first diagram illustrating an operation of the receiving side apparatus according to the second embodiment.

FIG. 15 is a second diagram illustrating an operation of the receiving side apparatus according to the second embodiment.

FIG. 16 is a diagram illustrating a transmitting side apparatus according to a first modification of the second embodiment.

FIG. 17 is a diagram illustrating a receiving side apparatus according to the first modification of the second embodiment.

### DESCRIPTION OF EMBODIMENTS

### Overview of Embodiments

A communication method according to first and second embodiments is a method in a communication apparatus for transmitting an encoded bit sequence obtained by encoding an information bit sequence at a target coding rate. The communication method includes: a grouping step of dividing the information bit sequence to generate multiple information bit groups having different degrees of importance; an encoding step of individually encoding each of the multiple information bit groups at a coding rates set according to a corresponding degree of importance while maintaining a total coding rate for the multiple information bit groups to be the target coding rate; and a coupling step of coupling multiple encoded bit groups obtained by individually encoding the multiple information bit groups, to generate the encoded bit sequence. In the encoding step, a coding rate applied to an information bit group having a high degree of importance is set to be lower than a coding rate applied to an information bit group having a low degree of importance.

In the first and second embodiments, the information bit group having the high degree of importance is an information bit group including an MSB of the information bit sequence. The information bit group having the low degree of importance is an information bit group including an LSB of the information bit sequence.

In the first and second embodiments, the communication method further includes: a notification step of notifying, to another communication apparatus that receives the encoded bit sequence, content of a change in response to changing at least one of total number of the multiple information bit groups and number of bits of each of the multiple information bit groups.

In the second embodiment, the grouping step includes: a step of dividing each of multiple information bit sequences to generate multiple information bit groups having different degrees of importance for each information bit sequence; and a step of coupling the information bit groups having same degree of importance to generate multiple coupled information bit sequences having different degrees of importance as a new information bit sequence. The encoding step includes a step of individually encoding each of the multiple coupled information bit sequences at a coding rates set according to a corresponding degree of importance while maintaining a total coding rate for the multiple coupled information bit sequences to be the target coding rate. The coupling step includes a step of coupling multiple coupled encoded bit sequences obtained by individually encoding the multiple coupled information bit sequences. In the encoding step, a coding rate applied to a coupled information bit sequence having a high degree of importance is set to be lower than a coding rate applied to a coupled information bit sequence having a low degree of importance.

In the second embodiment, the coupled information bit sequence having the high degree of importance is a coupled information bit sequence obtained by coupling multiple information bit groups each of which includes an MSB of information bit sequence. The coupled information bit sequence having the low degree of importance is a coupled information bit sequence obtained by coupling multiple information bit groups each of which includes an LSB of information bit sequence.

A communication method according to first and second embodiments is a method in a communication apparatus for receiving an encoded bit sequence obtained by encoding an information bit sequence at a target coding rate. The communication method includes: a classifying step of dividing the encoded bit sequence to generate multiple encoded bit groups having different coding rates; a step of decoding each of the multiple encoded bit groups; a coupling step of coupling multiple information bit groups having different degrees of importance obtained by decoding the multiple encoded bit groups, to generate the information bit sequence. Each of the multiple information bit groups is individually encoded at a coding rates set according to a corresponding degree of importance while maintaining a total coding rate for the multiple information bit groups to be the target coding rate. A coding rate of an information bit group having a high degree of importance is set to be lower than a coding rate of an information bit group having a low degree of importance.

In the first and second embodiments, the information bit group having the high degree of importance is an information bit group including an MSB of the information bit sequence. The information bit group having the low degree of importance is an information bit group including an LSB of the information bit sequence.

In the first and second embodiments, the communication method further includes: a step of receiving, from another communication apparatus that transmits the encoded bit sequence, a notification indicating content of a change in response to changing at least one of total number of the multiple information bit groups and number of bits of each of the multiple information bit groups.

In the second embodiment, the classifying step includes a step of classifying an encoded bit sequence obtained by coupling multiple coupled encoded bit sequences into the multiple coupled encoded bit sequences having different coding rates. The decoding step includes a step of decoding each of the multiple coupled encoded bit sequences. The coupling step includes: a step of classifying each of multiple coupled information bit sequences having different degrees of importance obtained by decoding the multiple coupled encoded bit sequences into multiple information bit groups; and a step of coupling the information bit groups corresponding to each information bit sequence to generate multiple information bit sequences. Each of the multiple coupled information bit sequences is individually encoded at a coding rates set according to a corresponding degree of importance while maintaining a total coding rate for the multiple coupled information bit sequences to be the target coding rate. A coding rate of a coupled information bit sequence having a high degree of importance is set to be lower than a coding rate of a coupled information bit sequence having a low degree of importance.

In the second embodiment, the coupled information bit sequence having the high degree of importance is a coupled information bit sequence obtained by coupling multiple information bit groups each of which includes an MSB of information bit sequence. The coupled information bit sequence having the low degree of importance is a coupled information bit sequence obtained by coupling multiple information bit groups each of which includes an LSB of information bit sequence.

A communication apparatus according to first and second embodiments transmits an encoded bit sequence obtained by encoding an information bit sequence at a target coding rate. The communication apparatus includes a processor. The processor is configured to execute: a grouping process of dividing the information bit sequence to generate multiple information bit groups having different degrees of importance; an encoding process of individually encoding each of the multiple information bit groups at a coding rates set according to a corresponding degree of importance while maintaining a total coding rate for the multiple information bit groups to be the target coding rate; and a coupling process of coupling multiple encoded bit groups obtained by individually encoding the multiple information bit groups, to generate the encoded bit sequence. In the encoding process, the processor sets a coding rate applied to an information bit group having a high degree of importance to be lower than a coding rate applied to an information bit group having a low degree of importance.

A communication apparatus according to first and second embodiments receives an encoded bit sequence obtained by encoding an information bit sequence at a target coding rate. The communication apparatus includes a processor. The processor is configured to execute: a classifying process of dividing the encoded bit sequence to generate multiple encoded bit groups having different coding rates; a process of decoding each of the multiple encoded bit groups; a coupling process of coupling multiple information bit groups having different degrees of importance obtained by decoding the multiple encoded bit groups, to generate the information bit sequence. Each of the multiple information bit groups is individually encoded at a coding rates set according to a corresponding degree of importance while maintaining a total coding rate for the multiple information bit groups to be the target coding rate. A coding rate of an information bit group having a high degree of importance is set to be lower than a coding rate of an information bit group having a low degree of importance.

### First Embodiment

Hereinafter, an embodiment in which the present disclosure is applied to the LTE standardized in the 3rd Generation Partnership Project (3GPP) will be described with reference to the appended drawings.

(System Configuration)

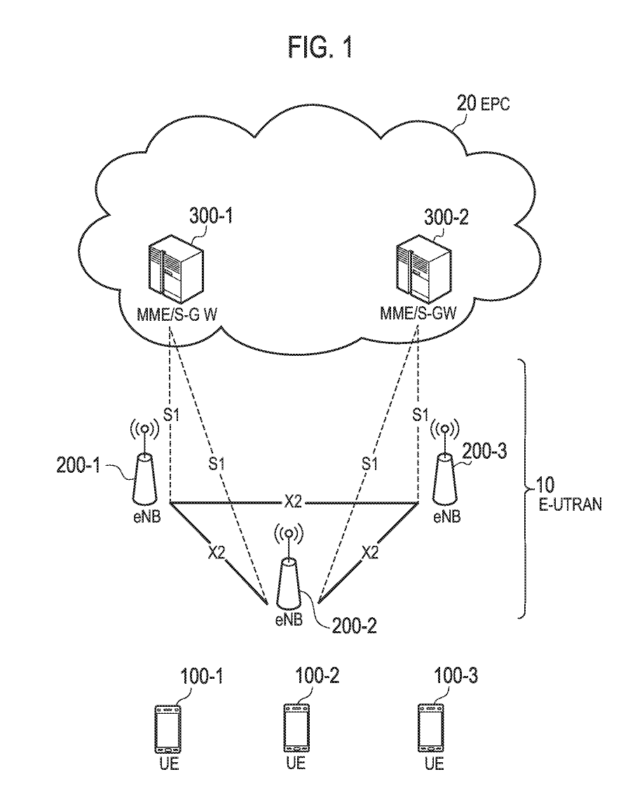

FIG. 1 is a configuration diagram illustrating an LTE system according to a first embodiment. The LTE system includes multiple user equipments (UEs) 100, an evolved-UMTS terrestrial radio access network (E-UTRAN) 10, and an evolved packet core (EPC) 20 as illustrated in FIG. 1. The E-UTRAN 10 corresponds to a radio access network, and the EPC 20 corresponds to a core network. The E-UTRAN 10 and the EPC 20 configure a network of the LTE system.

The UE 100 is a mobile communication apparatus, and performs radio communication with a cell (a serving cell) of a connection destination. The UE 100 corresponds to a user terminal.

The E-UTRAN 10 includes multiple evolved Node-Bs (eNBs) 200. The eNB 200 corresponds to a base station. The eNB 200 manages one or more cells, and performs radio communication with the UE 100 that has established a connection with its own cell. A “cell” is used as a term indicating a function of performing radio communication with the UE 100 as well as a term indicating a minimum unit of a radio communication area.

The eNB 200 has a radio resource management (RRM) function, a user data routing function, a measurement control function for mobility control/scheduling, and the like.

The EPC 20 includes multiple mobility management entity/serving-gateways (MME/S-GWs) 300. The MME is a network node that performs various kinds of mobility control on the UE 100 and corresponds to a control station. The S-GW is a network node that performs user data transfer control and corresponds to a switching station. The EPC 20 configured with the MME/S-GWs 300 accommodates the eNB 200.

The eNBs 200 are connected to each other via an X2 interface. The eNB 200 is connected with the MME/S-GW 300 via an S1 interface.

Next, configurations of the UE 100 and the eNB 200 will be described.

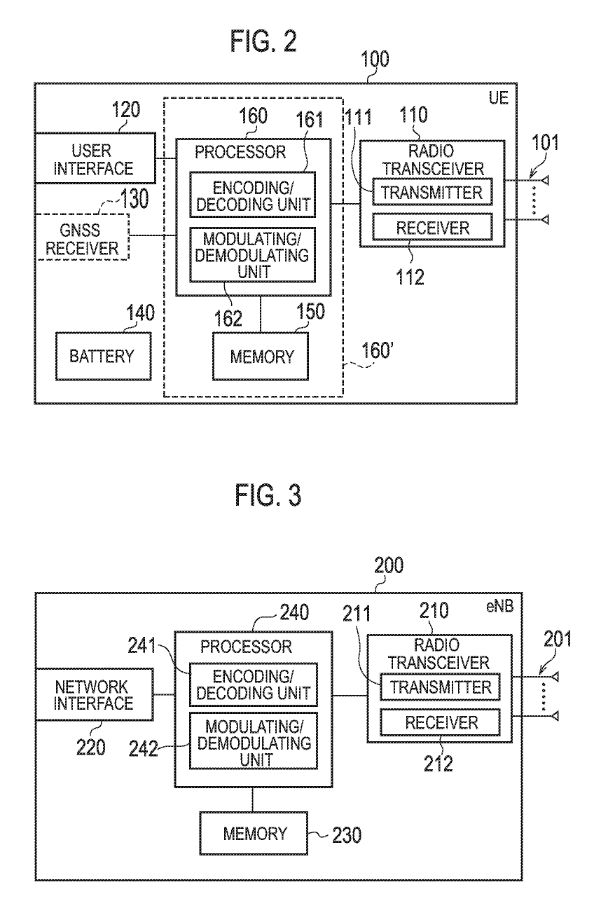

FIG. 2 is a block diagram illustrating the UE 100. The UE 100 includes multiple antennas 101, a radio transceiver 110, a user interface 120, a global navigation satellite system (GNSS) receiver 130, a battery 140, a memory 150, and a processor 160 as illustrated in FIG. 2. The UE 100 may not include the GNSS receiver 130. The memory 150 may be integrated with the processor 160, and this set (that is, a chip set) may be used as the processor 160′.

Multiple antennas 101 and the radio transceiver 110 are used for transmission and reception of a radio signal. The radio transceiver 110 includes a transmitter 111 that converts a baseband signal (a transmission signal) output from the processor 160 into a radio signal and transmits the radio signal through multiple antennas 101. The radio transceiver 110 includes a receiver 112 that converts a radio signal received through multiple antennas 101 into a baseband signal (a reception signal) and outputs the baseband signal to the processor 160.

The user interface 120 is an interface with the user who carries the UE 100, and includes, for example, a display, a microphone, a speaker, various kinds of buttons, and the like. The user interface 120 receives an operation from the user, and outputs a signal indicating content of the operation to the processor 160. In order to obtain position information indicating a geographical position of the UE 100, the GNSS receiver 130 receives a GNSS signal and outputs the received signal to the processor 160. The battery 140 accumulates electric power to be supplied to the respective blocks of the UE 100.

The memory 150 stores a program executed by the processor 160 and information used for a process performed by the processor 160. The processor 160 includes an encoding/decoding unit 161 that performs signal processing related to encoding and decoding of the baseband signal and a modulating/demodulating unit 162 that performs signal processing related to modulation and demodulation of the baseband signal. The processor 160 executes various kinds of control and various kinds of communication protocols which will be described later.

FIG. 3 is a block diagram illustrating the eNB 200. The eNB 200 includes multiple antennas 201, a radio transceiver 210, a network interface 220, a memory 230, and a processor 240 as illustrated in FIG. 3. The memory 230 and the processor 240 configure a base station side controller.

Multiple antennas 201 and the radio transceiver 210 are used for transmission and reception of a radio signal. The radio transceiver 210 includes a transmitter 211 that converts a baseband signal (a transmission signal) output from the processor 240 into a radio signal and transmits the radio signal through multiple antennas 201. The radio transceiver 210 includes a receiver 212 that converts a radio signal received by multiple antennas 201 into a baseband signal (a reception signal) and outputs the baseband signal to the processor 240.

The network interface 220 is connected with a neighboring eNB 200 via the X2 interface and connected with the MME/S-GW 300 via the Si interface. The network interface 220 is used for communication performed on the X2 interface and communication performed on the Si interface.

The memory 230 stores a program executed by the processor 240 and information used for a process performed by the processor 240. The processor 240 includes an encoding/decoding unit 241 that performs signal processing related to encoding and decoding of the baseband signal and a modulating/demodulating unit 242 that performs signal processing related to modulation and demodulation of the baseband signal. The processor 240 executes various kinds of control and various kinds of communication protocols which will be described later.

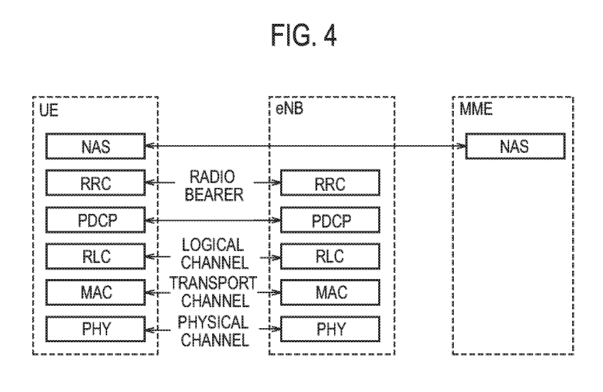

FIG. 4 is a protocol stack diagram of a radio interface in the LTE system. As illustrated in FIG. 4, a radio interface protocol is classified into layers 1 to 3 of an OSI reference model, and the layer 1 is a physical (PHY) layer. The layer 2 includes a media access control (MAC) layer, a radio link control (RLC) layer, and a packet data convergence protocol (PDCP) layer. The layer 3 includes a radio resource control (RRC) layer.

The PHY layer performs encoding/decoding, modulation/demodulation, antenna mapping/demapping, and resource mapping/demapping. Data is transmitted through a physical channel between the PHY layer of the UE 100 and the PHY layer of the eNB 200.

The MAC layer performs preferential control of data, a retransmission process by hybrid ARQ (HARQ), and the like. Data is transmitted through a transport channel between the MAC layer of the UE 100 and the MAC layer of the eNB 200. The MAC layer of the eNB 200 includes a scheduler for deciding transport formats (a transport block size and a modulation and coding scheme (MCS)) of an uplink and a downlink and an allocation resource block.

The RLC layer transmits data to an RLC layer of a receiving side using the functions of the MAC layer and the PHY layer. Between Data is transmitted through a logical channel between the RLC layer of the UE 100 and the RLC layer of the eNB 200. The PDCP layer performs header compression/decompression and encryption/decryption.

The RRC layer is defined only in a control plane. A control message (an RRC message) for various kinds of settings is transmitted through a radio bearer between the RRC layer of the UE 100 and the RRC layer of the eNB 200. The RRC layer controls the logical channel, the transport channel, and the physical channel in response to establishment, re-establishment, and release of the radio bearer. When there is an RRC connection between the RRC of the UE 100 and the RRC of the eNB 200, the UE 100 is in a connected state (an RRC connected state), and otherwise, the UE 100 is in an idle state (an RRC idle state). A non-access stratum (NAS) layer positioned above the RRC layer performs session management, mobility management, and the like.

(Communication Method According to First Embodiment)

Next, a communication method according to the first embodiment will be described. The communication method according to the first embodiment relates to encoding and decoding in communication between the UE 100 and the eNB 200.

One of the UE 100 and the eNB 200 is a communication apparatus (hereinafter, referred to as a “transmitting side apparatus”) at the transmitting side, and the other is a communication apparatus (hereinafter, referred to as a “receiving side apparatus”) at the receiving side.

The communication method to be described below is executed mainly through the encoding/decoding unit 161 of the UE 100 and the encoding/decoding unit 241 of the eNB 200.

### (1) Overview of First Embodiment

In the error correction technique, the transmitting side apparatus performs encoding by adding a redundancy (redundant bits) to an information bit sequence, and transmits an encoded bit sequence obtained by the encoding. The receiving side apparatus performs decoding by detecting and correcting a transmission error of the encoded bit sequence using the redundancy, and obtains an original information bit sequence.

A ratio (N/K) of the number (N) of bits of an information bit sequence to the number (K) of bits of an encoded bit sequence is referred to as a “coding rate.” Generally, in the case of the same encoding method, as the coding rate decreases, an error correction performance is improved, but the redundancy, that is, an overhead increases. Meanwhile, as the coding rate increases, the overhead decreases, but the error correction performance decreases.

By the way, the information bit sequence includes bits having a high degree of importance and bits having a low degree of importance. For example, a transmission error of a most significant bit (MSB) of the information bit sequence is larger in an error occurring as a result than a transmission error of a least significant bit (LSB), and thus the MSB is more important than the LSB.

For example, in an information bit sequence “111” (which indicates “7” as a decimal number), a leftmost digit “1” is assumed to be an MSB, and a rightmost digit “1” is assumed to be an LSB. If “0” is erroneously received as the MSB instead of “1,” “011” which indicates “3” as a decimal number is obtained instead of “111”, and thus a square error with “7” is 16 (=(7−3)²). Meanwhile, when “0” is erroneously received as the LSB, “110” which indicates “6” as a decimal number is obtained instead of “111,” and thus a square error with “7” is 1 (=(7−6)²).

Here, when the same error correction code is applied to the MSB and the LSB, the MSB and the LSB have an error occurring at the same probability. In other words, a probability that a large error will occur is the same as a probability that a small error will occur.

In this regard, in the first embodiment, a more robust error correction code is applied to the MSB, and a relative fragile error correction code is applied to the LSB in order to maintain a total coding rate. By intensively protecting the MSB as described above, the occurrence of a large error is prevented.

### (2) Transmitting Side Apparatus According to First Embodiment

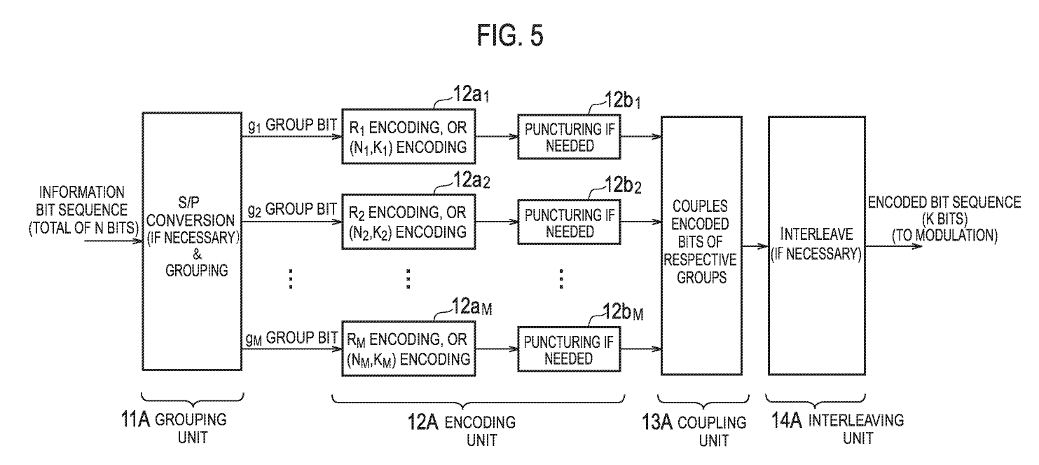

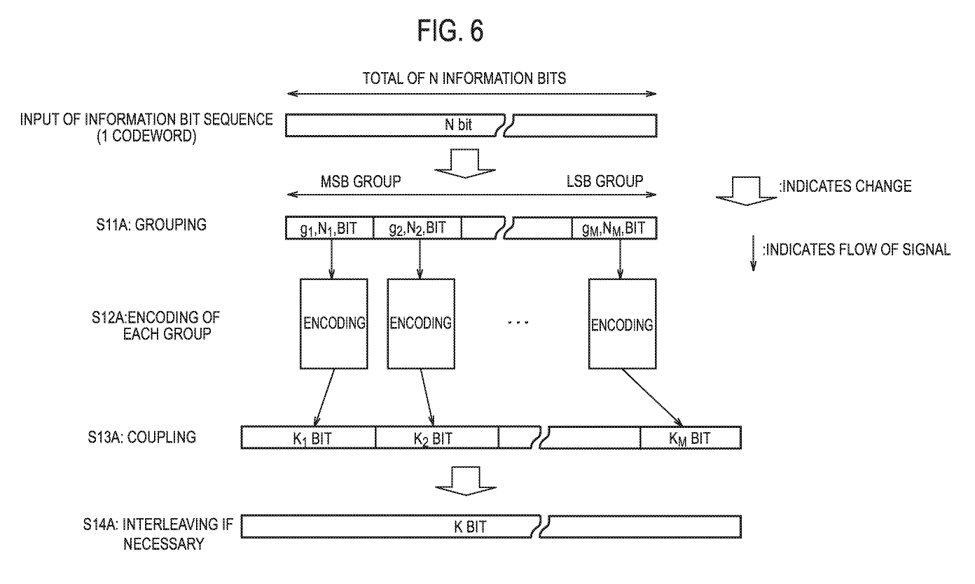

Next, the transmitting side apparatus according to the first embodiment will be described. FIG. 5 is a block diagram illustrating the transmitting side apparatus according to the first embodiment. FIG. 6 is a diagram illustrating an operation of the transmitting side apparatus according to the first embodiment. In FIG. 5 and the drawings subsequent thereto, a block or a process indicated by “if necessary” or “if needed” is a block or a process that can be omitted in the present disclosure.

The transmitting side apparatus transmits the encoded bit sequence obtained by encoding the information bit sequence at the target coding rate as illustrated in FIG. 5. The transmitting side apparatus may further include: a grouping unit 11A that divides the information bit sequence to generate multiple information bit groups having different degrees of importance; an encoding unit 12A that individually encodes each of multiple information bit groups at a coding rates set according to a corresponding degree of importance while maintaining a total coding rate for multiple information bit groups to be the target coding rate; and a coupling unit 13A that couples multiple encoded bit groups obtained by individually encoding multiple information bit groups to generate an encoded bit sequence. The transmitting side apparatus may further include an interleaving unit 14A that interleave the encoded bit sequence.

The encoding unit 12A sets the coding rate applied to the information bit group having the high degree of importance to be lower than the coding rate applied to the information bit group having the low degree of importance. In the first embodiment, the information bit group having the high degree of importance is an information bit group (an MSB group) including the MSB of the information bit sequence. The information bit group having the low degree of importance is an information bit group (an LSB group) including the LSB of the information bit sequence.

The encoding unit 12A includes M encoders 12a1 to 12aM. Here, when the turbo code is used, it is indicated by “Ri encoding” (Ri is the coding rate), and when any other encoding method is used, it is indicated by “(Ni, Ki) encoding” (Ni is the number of information bits, and Ki is the number of encoded bits), and the encoding method is not particularly limited. The encoding unit 12A may further include M puncturers 12b1 to 12bM.

Next, an operation of the transmitting side apparatus according to the first embodiment will be described with reference to FIGS. 5 and 6. Hereinafter, the information bit sequence (hereinafter, referred to appropriately as “1 codeword”) is assumed to have N bits, and the encoded bit sequence that has undergone the error correction encoding (hereinafter, referred to appropriately as “encoding”) is assumed to have K bits (K>N).

As illustrated in FIG. 6, in step S11A, the grouping unit 11A groups N bits of the information bit sequence (1 codeword) into M information bit groups “g1, g2, . . . , gM” starting from the MSB (the information bit sequence may be equally or unequally divided). The “grouping” means dividing a chunk of bits (for example, a codeword) into multiple small groups according to a parameter that is set in advance. Further, when the MSB and the LSB of the information bit sequence are arranged in order, the grouping unit 11A performs sorting before the grouping.

If g1 is the MSB group, gM is the LSB group, and the number of bits of each information bit group is Ni (i=1, 2, . . . , M), the following Formula is held.

$${\sum }_{i = 1}^{M} {N}_{t} = N \qquad [ Formula . 1 ]$$

In step S12A, the encoding unit 12A individually encodes each of the M information bit groups “g1, g2, . . . , gM” at a coding rates set according to a corresponding degree of importance. If the number of bits of each encoded group is Ki (i=1, 2, . . . , M), the following Formula is held.

$${\sum }_{i = 1}^{M} {K}_{i} = K \qquad [ Formula . 2 ]$$

“N/K=R” refers to the coding rate, and in the case of the same encoding method, the error correction performance can be ordered according to a value of R. In the first embodiment, error correction strength/performance of encoding are indicated using the coding rate Ri (=Ni/Ki) of each information bit group.

“R” is a total target coding rate. Basically, “R” is a parameter depending to the system to which the present disclosure is applied and set according to performance requirements of the system. For example, in the case of the LTE, the turbo code in which R is ⅓ is often used, and thus R is set to ⅓.

Here, when the encoding methods of the information bit groups are the same, and the coding rates are set to be equal as follows, error rates of the information bit groups are the same, and thus it is hard to achieve the purpose of intensively protecting the MSB group.

$$\frac{{N}_{1}}{{K}_{1}} = \frac{{N}_{2}}{{K}_{2}} = … = \frac{{N}_{M}}{{K}_{M}} \qquad [ Formula . 3 ]$$

Thus,

R₁<R₂< . . . <R_{M} [Formula. 4]

In other words,

$$\frac{{N}_{1}}{{K}_{1}} < \frac{{N}_{2}}{{K}_{2}} < … < \frac{{N}_{M}}{{K}_{M}} \qquad [ Formula . 5 ]$$

is necessary. In the case of “N1=N2= . . . =NM” (that is, when a 1 codeword is equally divided), it is desirable to set “K1>K2> . . . >KM” simply.

When a 1 codeword is equally divided, a relation between the coding rate Ri (i=1, 2, . . . , M) of each group and the target coding rate is as follows.

$$\begin{matrix}R = \frac{M}{\frac{1}{{R}_{1}} + \frac{1}{{R}_{2}} + … + \frac{1}{{R}_{M}}} \\ Alternatively , & [ Formula . 6 ] \\ \frac{M}{R} = \frac{1}{{R}_{1}} + \frac{1}{{R}_{2}} + … + \frac{1}{{R}_{M}} & [ Formula . 7 ]\end{matrix}$$

The following description will proceed with a simple example of “M=2, N1=N2.” Based on Formula. 6 and M=2,

$$\begin{matrix}R = \frac{2}{\frac{1}{{R}_{1}} + \frac{1}{{R}_{2}}} \\ = \frac{2 {R}_{1} {R}_{2}}{{R}_{1} + {R}_{2}}\end{matrix} \qquad [ Formula . 8 ]$$

is obtained. The following Formula is derived from the above Formula.

$${R}_{2} = \frac{{RR}_{1}}{2 {R}_{1} - R} \qquad [ Formula . 9 ]$$

Since R2>0, 2R1−R>0, that is, R1>R/2 is obtained. As a result, in the case of the turbo code of R=⅓ which is often used in the LTE, it is limited to R1>⅙. For example, there are choices of R1=¼ and R2=½.

In an actual operation (implementation), it is considered that, first, R1 and R2 are set, encoding is performed using a code such as the turbo code, and the number of encoded bits is adjusted to correspond to the total coding rate R by performing puncturing appropriately (that is, the number of bits is adjusted by puncturing so that K1+K2=K is satisfied).

Alternatively, the MSB group is encoded using the turbo code of R1 (within the range of K1≦K−N2), and an appropriate error correction code in which a code length after encoding is K−K1 is applied to the LSB group (since K1≦K−N2, K−K1≧N2).

In the case of N1≠N2, a mathematical calculation is complicated, but a concept is the same. When it is hard to solve mathematically clearly, it is adjusted in a trial-and-error manner according to “Formula. 4” above. Alternatively, the above-mentioned puncturing method is applied. That is, R1, R2, . . . , and RM are set, encoding is performed using a code such as the turbo code, puncturing is appropriately performed on an encoded bit sequence, and the number of bits is adjusted to satisfy K1+K2+ . . . +KM=K. Alternatively, for an important group, R1, R2, . . . are set, and encoding is performed using the turbo code, and for the remaining groups, an appropriate error correction code is applied within a possible range.

In step S13A, the coupling unit 13A couples the M encoded bit groups obtained by individually the M information bit groups and generates the encoded bit sequence.

In step S14A, the interleaving unit 14A interleaves the encoded bit sequence output from the coupling unit 13A, and outputs the interleaved encoded bit sequence to a modulation unit. The interleaving may be performed once after the coupling or may be performed once for each group and then performed again after the coupling.

### (3) Receiving Side Apparatus According to First Embodiment

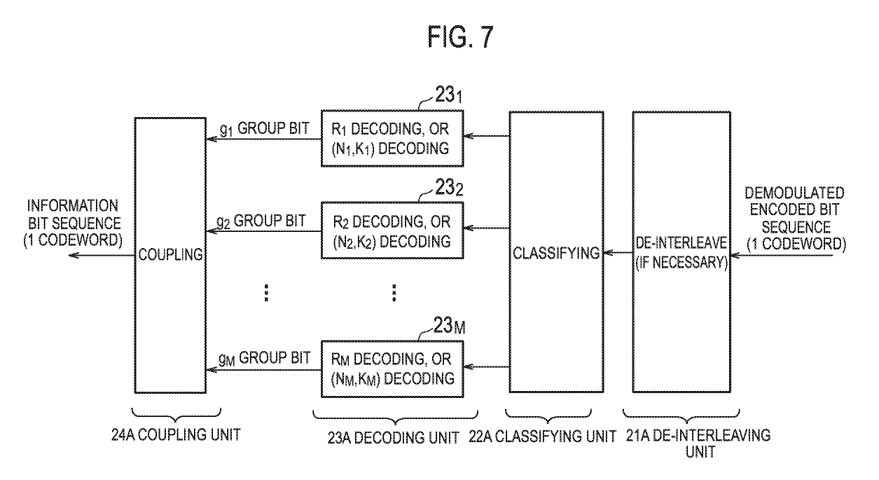

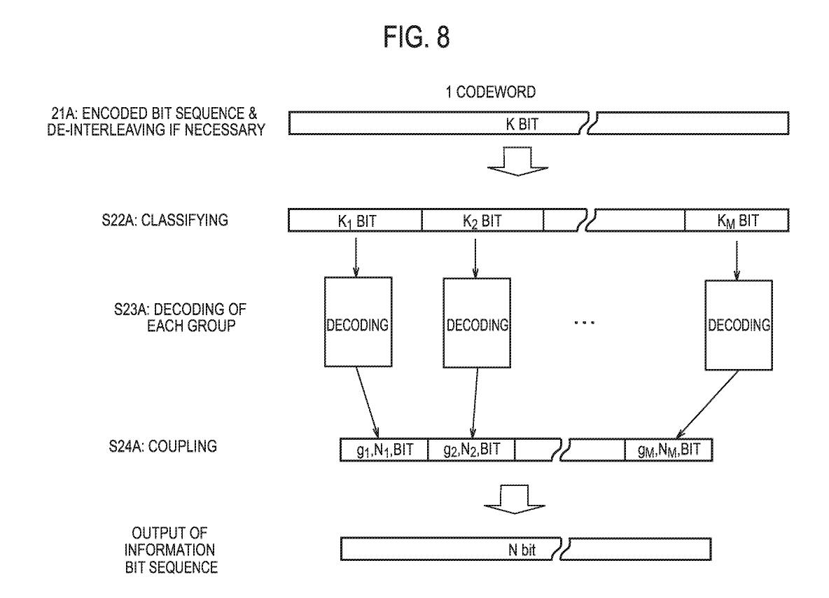

Next, a receiving side apparatus according to the first embodiment will be described. The receiving side apparatus according to the first embodiment performs an opposite process to that of the transmitting side apparatus according to the first embodiment. FIG. 7 is a block diagram illustrating the receiving side apparatus according to the first embodiment. FIG. 8 is a diagram illustrating an operation of the receiving side apparatus according to the first embodiment.

The receiving side apparatus may include a de-interleaving unit 21A that de-interleaves the encoded bit sequence output from a demodulation unit as illustrated in FIG. 7. The receiving side apparatus includes: a classifying unit 22A that generates multiple encoded bit groups having different coding rates by dividing the encoded bit sequence; a decoding unit 23A that decodes each of multiple encoded bit groups; and a coupling unit 24A that couples multiple information bit groups having different degrees of importance obtained by decoding multiple encoded bit groups and generates an information bit sequence.

As described above, each of the M information bit groups (g1, g2, . . . , gM) is individually encoded at a coding rates set according to a corresponding degree of importance (Ri) while maintaining the total coding rate of the M information bit groups (g1, g2, . . . , gM) to be the target coding rate (R). The coding rate of the information bit group (the MSB group) having the high degree of importance is set to be lower than the coding rate of the information bit group (the LSB group) having the low degree of importance.

The decoding unit 23A includes M decoders 231 to 23M. Here, when the turbo code is used, it is indicated by “Ri decoding,” and when any other encoding method is used, it is indicated by “(Ni, Ki) decoding,” and the encoding method is not particularly limited.

Next, an operation of the receiving side apparatus according to the first embodiment will be described with reference to FIGS. 7 and 8.

As illustrated in FIG. 8, in step S21A, the de-interleaving unit 21A de-interleaves the encoded bit sequence.

In step S22A, the classifying unit 22A divides (classifies) the encoded bit sequence, and generates M encoded bit groups having different coding rates. The “classifying” means dividing (restoring) a large chunk of bits having multiple small groups into (to) the (original) small groups.

In step S23A, the decoding unit 23A decodes the M encoded bit groups.

In step S24A, the coupling unit 24A couples multiple information bit groups having different degrees of importance obtained by decoding the M encoded bit groups, and generates the information bit sequence, that is, outputs the original information bit sequence. Further, when the sorting process is performed in the transmitting side apparatus, the coupling unit 24A performs inverse sorting before outputting the information bit sequence.

### Effects of First Embodiment

As described above, the robust error correction code is applied to the MSB group, whereas the relatively fragile error correction code is applied to the LSB group in order to maintain the total coding rate. As described above, by intensively protecting the MSB group, it is possible to prevent the occurrence of a large error.

Effects according to the first embodiment will be described below. First, in the case in which the same coding rate is applied to the MSB and the LSB (that is, the MSB and the LSB have an error occurring at the same probability), if a 1-bit error occurs after decoding, a mean value of a square error is calculated by the following Formula:

$${e}_{1 avg}^{2} = {\sum }_{i = 1}^{N} {{p}_{t} ( {2}^{t - 1} )}^{2} = {\sum }_{i = 1}^{N} \frac{1}{N} {2}^{2 t - 2} = \frac{1}{N} \frac{{2}^{2 N} - 1}{3} \qquad [ Formula . 10 ]$$

Here, “pi” indicates a probability (=1/N) that an error will occur in a certain bit.

Meanwhile, in the case (an error occurrence probability of each information bit is indicated by pi, and an error is assumed to similarly occur in a 1 bit after decoding) of the first embodiment), the mean value of the square error is calculated by the following Formula:

$${e}_{2 avg}^{2} = {\sum }_{i = 1}^{N} {{p}_{t} ( {2}^{t - 1} )}^{2} = {\sum }_{t = 1}^{N} {p}_{i} {2}^{2 t - 2} \qquad [ Formula . 11 ]$$

Here, if M is 2, a probability that an error will occur in a certain bit in the LSB group is indicated by p1, a probability that an error will occur in a bit in the MSB group is indicated by p2, and N is an even number,

$${e}_{2 avg}^{2} = {\sum }_{t = 1}^{N \text{/} 2} {p}_{1} {2}^{2 t - 2} + {\sum }_{t = \frac{N}{2} + 1}^{N} {p}_{2} {2}^{2 t - 2} = \frac{{2}^{N} - 1}{3} ( {p}_{1} + {p}_{2} {2}^{N} ) \qquad [ Formula . 12 ]$$

is obtained. In order to compare the errors, a calculation is performed using the following Formula:

$$\begin{matrix}\frac{{e}_{1 avg}^{2}}{{e}_{2 avg}^{2}} = \frac{1}{N} \frac{{2}^{2 N} - 1}{3} \text{/} \frac{{2}^{N} - 1}{3} ( {p}_{1} + {p}_{2} {2}^{N} ) \\ = \frac{1}{N} \frac{{2}^{N} + 1}{{p}_{1} + {p}_{2} {2}^{N}}\end{matrix} \qquad [ Formula . 13 ]$$

Since an error is assumed to occur in only 1 bit, N/2·(p1+p2)=1, i.e., p1+p2=2/N, or p1=2/N−p2.

$$\frac{{e}_{1 avg}^{2}}{{e}_{2 avg}^{2}} = \frac{1}{N} \frac{{2}^{N} + 1}{\frac{2}{N} - {p}_{2} + {p}_{2} {2}^{N}} = \frac{{2}^{N} + 1}{2 + N {p}_{2} ( {2}^{N} - 1 )} \qquad [ Formula . 14 ]$$

With the purpose of the first embodiment, the following Formula needs to be held.

$$\frac{{e}_{1 avg}^{2}}{{e}_{2 avg}^{2}} = \frac{{2}^{N} + 1}{2 + N {p}_{2} ( {2}^{N} - 1 )} > 1 \qquad [ Formula . 15 ]$$

That is,

2^{N}+1>2+Np₂(2N−1) [Formula. 16]

Since the effects of the first embodiment are shown from this Formula, it is understood that the following Formula is necessary:

$${p}_{2} < \frac{1}{N} \qquad [ Formula . 17 ]$$

If it is the same encoding as the LSB group, p2=1/N, and thus when it is encoding more robust than the LSB group, the above Formula is held, and it is understood that there is an effect in which the square error is reduced.

If a probability that an error will occur after the bit of the MSB group is decoded is assumed to be ½ at the time of the same encoding, i.e., p2=½N, and N is sufficiently large (e.g., N>10), the square error in the first embodiment is about a second (½) of that at the time of the same encoding. It may be considered that there is a gain of 3 dB (it is about 1/10 when p2 is 1/10 of that at the time of the same encoding).

$$\begin{matrix}\frac{{e}_{1 avg}^{2}}{{e}_{2 avg}^{2}} = \frac{{2}^{N} + 1}{2 + N {p}_{2} ( {2}^{N} - 1 )} = \frac{{2}^{N} + 1}{2 + N \frac{1}{2 N} ( {2}^{N} - 1 )} \\ = 2 \frac{ {2}^{N} + 1}{{2}^{N} + 3} = 2 ( 1 - \frac{2}{{2}^{N} + 3} )\end{matrix} \qquad [ Formula . 18 ]$$

### First Modification of First Embodiment

In the first embodiment, a method of setting the number “M” of groups is not particularly mentioned, but a setting of M=2 or 3 is considered to be appropriate from a point of view in which an important part of the information bit sequence is intensively protected by applying a more robust error correction code to the important part of the information bit sequence.

Further, when M=2, there is a limitation of R1>R/2, and in the case of the M groups, there is a limitation of R1>R/M. When R is large, there are no many choices. There are the following several examples:
M=2, R1=¼, and R2=½ are selected when the target coding rate R is ⅓ (there is also a choice of M=3, R1=¼, R2=⅓, and R3=½);
M=2, R1=⅙, and R2=¼ or M=3, R1=⅛, R2=⅕, and R3=½ is selected when the target coding rate R is ⅕ (there are many choices); and
when the target coding rate R is 1/10 or less, since there are no many choices, it is appropriately selected according to the request of the system with reference to Formula [6].

### Second Modification of First Embodiment

The first embodiment has been described in connection with the example in which the grouping method is fixed, but the grouping method may be dynamically changed according to the request of the system. For example, the number of groups and the number of bits of each group are dynamically adjusted according to a change of a channel, an adjustment of a modulation scheme, or the like. When the number of groups and the number of bits of each group are dynamically adjusted, a notification is given to the receiving side through a control signal. For example, when at least one of a total (M) of the number of multiple information bit groups and the number (Ni) of bits of each of multiple information bit groups are changed, the transmitting side apparatus gives a notification indicating content of the change to the receiving side apparatus. The receiving side apparatus receives the notification indicating the content of the change, and reflects the content of the change in the process of the receiving side apparatus.

### Third Modification of First Embodiment

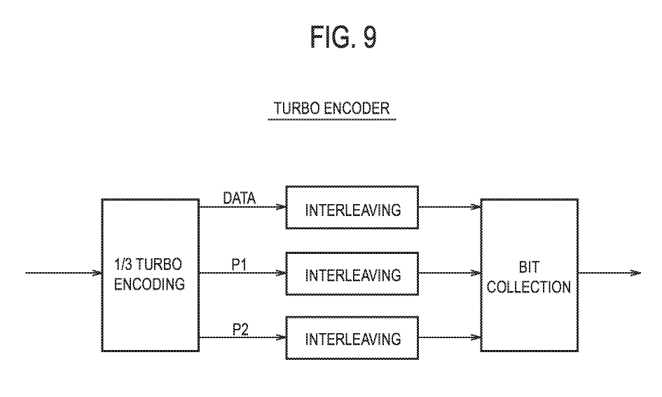

In the first embodiment, a configuration of the encoder is not particularly mentioned, but a turbo encoder can be used as the encoder as illustrated in FIG. 9. Firstly, the turbo encoder performs encoding at the coding rate of ⅓, and outputs data and parity bits (P1 and P2). Secondly, the turbo encoder interleaves each of the data and the parity bits (P1 and P2). Thirdly, the turbo encoder extracts (collects) bits from the data and the parity bits (P1 and P2), and outputs encoded bits.

### Fourth Modification of First Embodiment

In the first embodiment, a case in which an error is detected in the receiving side apparatus is not particularly mentioned, but the decoding unit 23A of the receiving side apparatus that has received the encoded bit sequence discards the received encoded bit sequence when an error is detected at the MSB side (the MSB group) in the received encoded bit sequence. Meanwhile, when an error is detected at the LSB side (the LSB group), a predetermined value or an arbitrary value is inserted into the LSB side to make the received encoded bit sequence available. As a result, in the related art, when an error occurs, all information (the entire received encoded bit sequence) has to be discarded, but by allowing corruption of some information that is relatively unimportant, transmission efficiency of information can be improved.

### Second Embodiment

Next, a second embodiment will be described focusing on different points with the first embodiment.

### (1) Transmitting Side Apparatus According to Second Embodiment

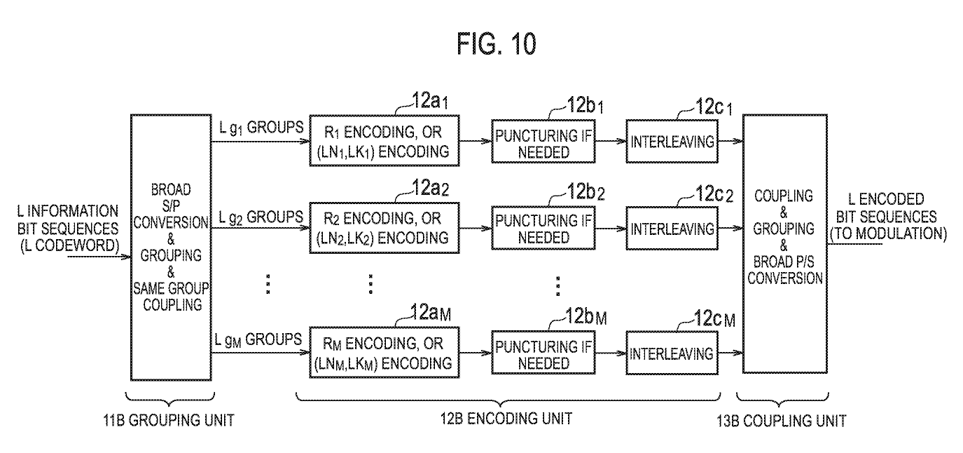

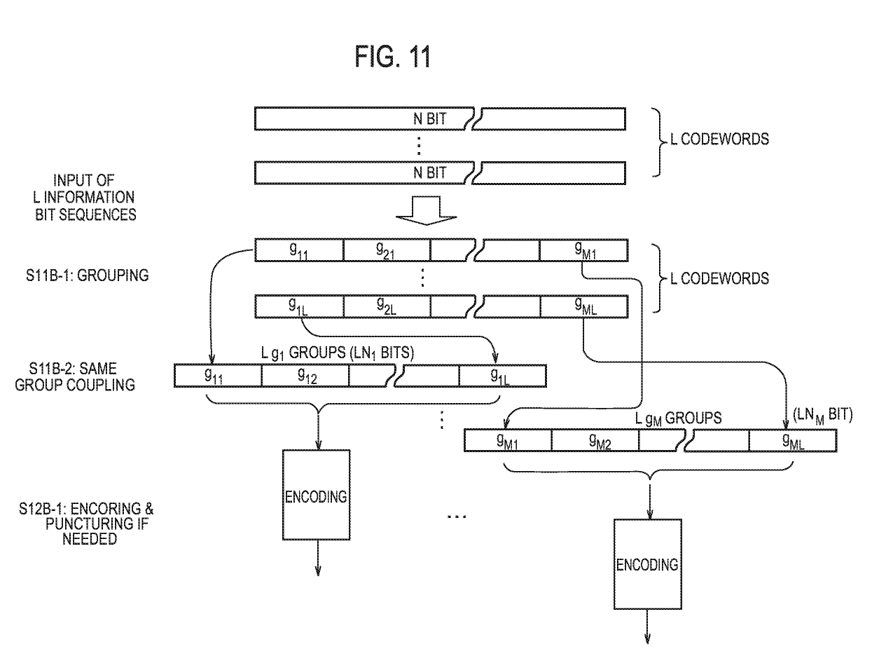

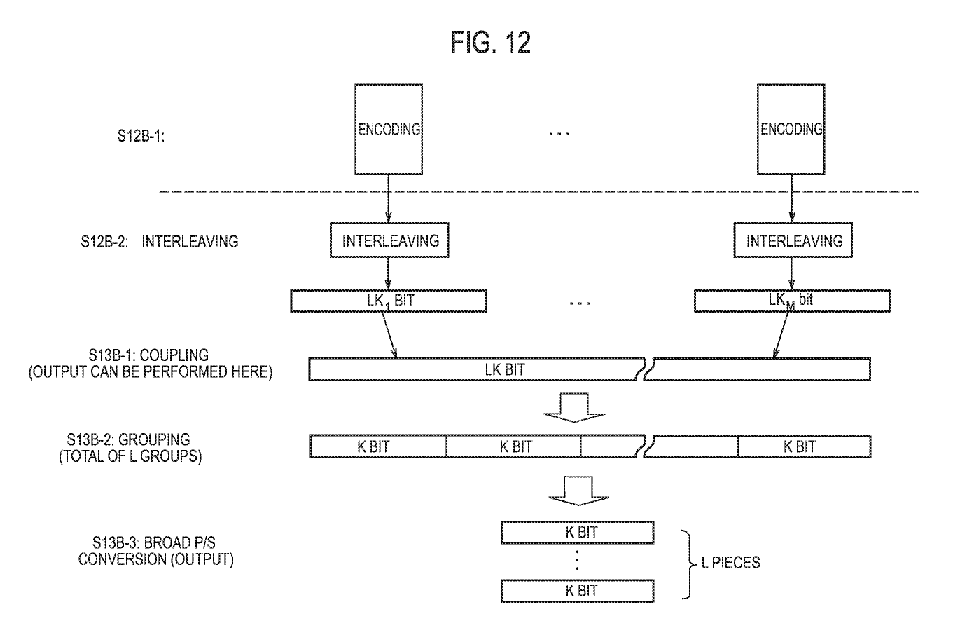

Next, the transmitting side apparatus according to the second embodiment will be described. FIG. 10 is a block diagram illustrating the transmitting side apparatus according to the second embodiment. FIGS. 11 and 12 are diagrams illustrating an operation of the transmitting side apparatus according to the second embodiment.

As illustrated in FIG. 10, a grouping unit 11B divides multiple information bit sequences (L information bit sequences) and generates M information bit groups having different degrees of importance for each information bit sequence. Then, the grouping unit 11B couples the information bit groups having the same degree of importance, and outputs M coupled information bit sequences having different degrees of importance. The grouping unit 11B also has a function of perform S/P conversion (hereinafter, referred to “broad S/P conversion”) on L information bit sequences in units of bit sequences (in units of codewords).

An encoding unit 12B individually encodes each of the M coupled information bit sequences at a coding rates set according to a corresponding degree of importance while maintaining the total coding rate for the M coupled information bit sequences to be the target coding rate. In the encoding unit 12B, the coding rate applied to the coupled information bit sequence having the high degree of importance is set to be lower than the coding rate applied to the coupled information bit sequence having the low degree of importance. A method of setting the coding rate is the same as in the first embodiment.

The encoding unit 12B includes M encoders 12a1 to 12aM. The encoding unit 12B may include M puncturers 12b1 to 12bM. The encoding unit 12B further includes M interleavers 12c1 to 12cM.

In the second embodiment, the coupled information bit sequence having the high degree of importance is the coupled information bit sequence obtained by coupling multiple information bit groups each of which includes the MSB of the information bit sequence. The coupled information bit sequence having the low degree of importance is the coupled information bit sequence obtained by coupling multiple information bit groups each of which includes the LSB of the information bit sequence.

A coupling unit 13B couples M coupled encoded bit sequences obtained by individually encoding the M coupled information bit sequences, and outputs (L) encoded bit sequences to the modulation unit. Alternatively, the coupling unit 13B may divide the encoded bit sequences obtained by the coupling into L groups and then outputs the L groups of bit sequences to the modulation unit. The coupling unit 13B also has a function of performing P/S conversion (hereinafter, referred to as “broad P/S conversion”) in units of bit sequences (in units of codewords).

Next, an operation of the transmitting side apparatus according to the second embodiment will be described with reference to FIGS. 10 to 12.

As illustrated in FIG. 11, the L information bit sequences (L codewards) are input to the grouping unit 11B. Each of the L information bit sequences has N bits.

In step S11B-1, the grouping unit 11B divides each of the L information bit sequences, and generates M information bit groups having different degrees of importance for each the information bit sequence. If the M information bit groups corresponding to a first information bit sequence are indicated by “g11, g21, . . . , gM1,” the M information bit groups corresponding to an L-th information bit sequence are indicated by “g1L, g2L, . . . , gML.”

In step S11B-2, the grouping unit 11B couples the information bit groups having the same degree of importance. For example, for the MSB group, the information bit groups g11, g12, . . . , g1L are coupled. For the LSB group, the information bit groups gM1, gM2, . . . , gML are coupled.

In step S12B-1, the encoding unit 12B individually encodes each of the M coupled information bit sequences at a coding rates set according to a corresponding degree of importance while maintaining the total coding rate for the M coupled information bit sequences to be the target coding rate.

As illustrated in FIG. 12, in step S12B-2, the encoding unit 12B interleaves each of the M coupled encoded bit sequences obtained by individually encoding the M coupled information bit sequences.

In step S13B-1, the coupling unit 13B couples the M interleaved coupled encoded bit sequences, and generates the encoded bit sequences. The encoded bit sequences may be output to the modulation unit.

In step S13B-2, the coupling unit 13B divides the encoded bit sequences obtained by coupling the M coupled encoded bit sequences into L groups.

In step S13B-3, the coupling unit 13B performs the broad P/S conversion on the L groups of the encoded bit sequences, and outputs the resulting bit sequences to the modulation unit.

### (2) Receiving Side Apparatus According to Second Embodiment

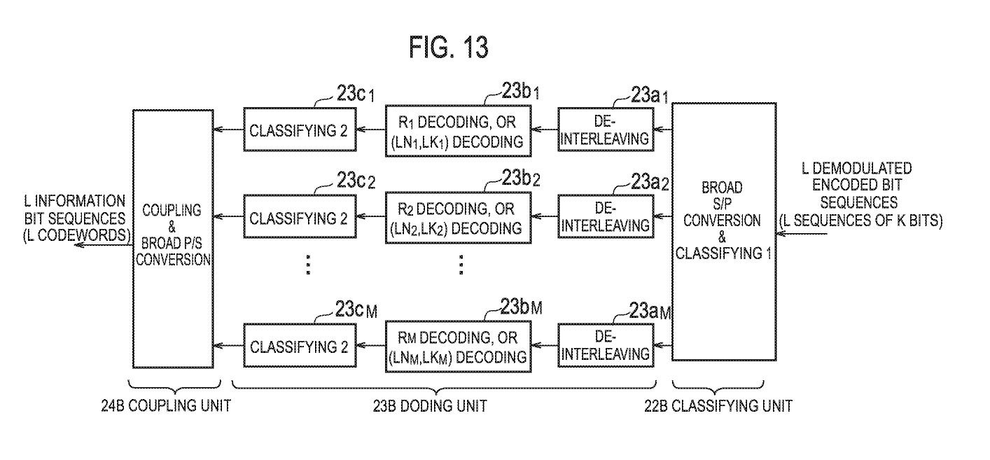

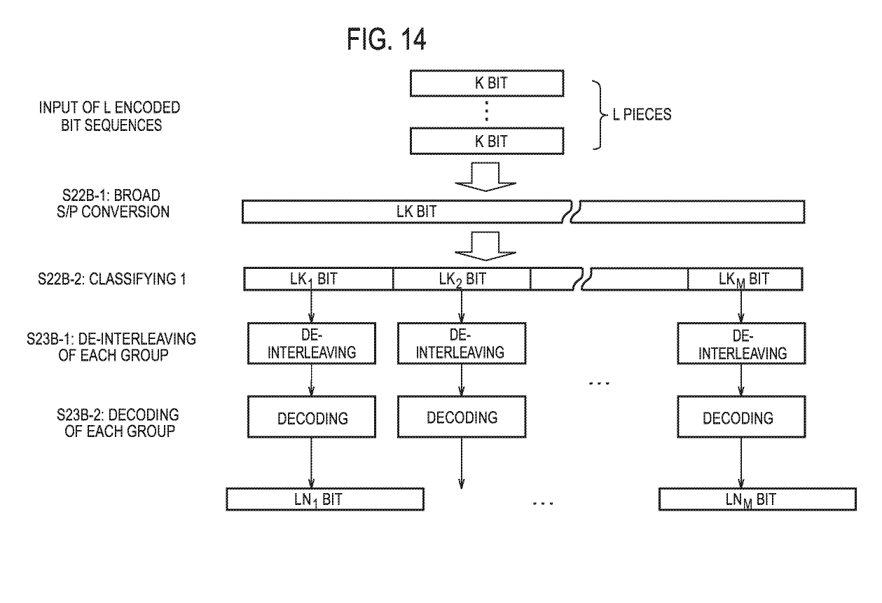

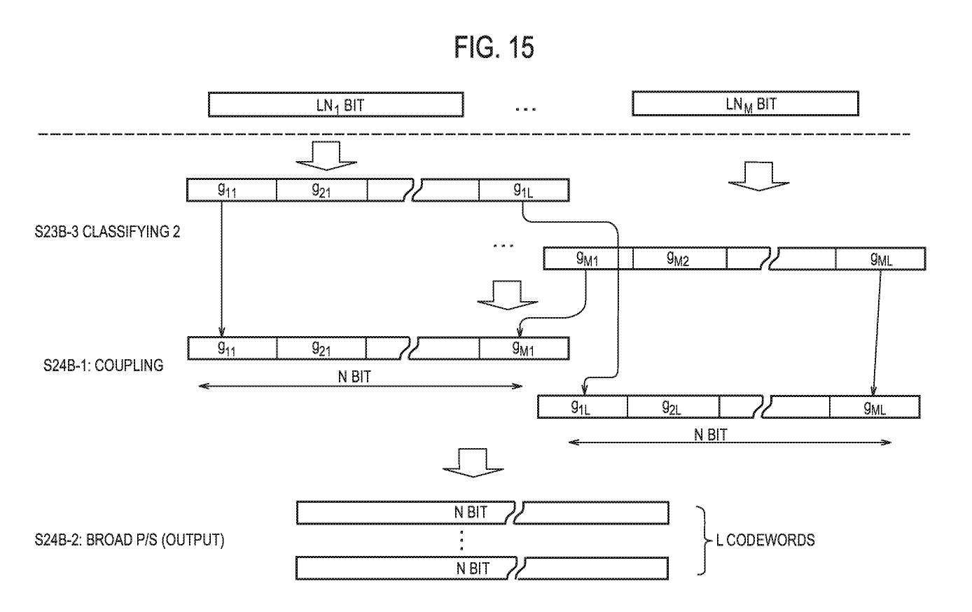

Next, the receiving side apparatus according to the second embodiment will be described. The receiving side apparatus according to the second embodiment performs an opposite process to that of the transmitting side apparatus according to the second embodiment. FIG. 13 is a block diagram illustrating the receiving side apparatus according to the second embodiment. FIGS. 14 and 15 are diagrams illustrating an operation of the receiving side apparatus according to the second embodiment.

As illustrated in FIG. 13, a classifying unit 22B classifies the encoded bit sequences received from the demodulation unit into the M coupled encoded bit sequences having different the coding rates.

A decoding unit 23B decodes each of the M coupled encoded bit sequences. The decoding unit 23B includes M de-interleavers 23a1 to 23aM, M decoders 23b1 to 23bM, and M classifiers 23c1 to 23cM.

The decoding unit 23B classifies the M coupled information bit sequences having the different degrees of importance obtained by decoding the M coupled encoded bit sequences into the information bit groups.

A coupling unit 24B couples the information bit groups corresponding to each information bit sequence, and generates the L information bit sequences.

Next, an operation of the receiving side apparatus according to the second embodiment will be described with reference to FIGS. 13 to 15.

As illustrated in FIG. 14, the L encoded bit sequences are input to the classifying unit 22B.

In step S22B-1, the classifying unit 22B performs the broad S/P conversion.

In step S22B-2, the classifying unit 22B classifies the M coupled encoded bit sequences.

In step S23B-1, the decoding unit 23B de-interleaves each of the M coupled encoded bit sequences.

In step S23B-2, the decoding unit 23B decodes each of the M de-interleaved coupled encoded bit sequences.

As illustrated in FIG. 15, in step S23B-3, the decoding unit 23B classifies the M coupled information bit sequences obtained by the decoding into the information bit groups.

In step S24B-1, the coupling unit 24B couples the information bit groups corresponding to each information bit sequence, and generates the L information bit sequences.

In step S24B-2, the coupling unit 24B performs the broad P/S conversion on the L information bit sequences, and outputs the resulting bit sequences.

### First Modification of Second Embodiment

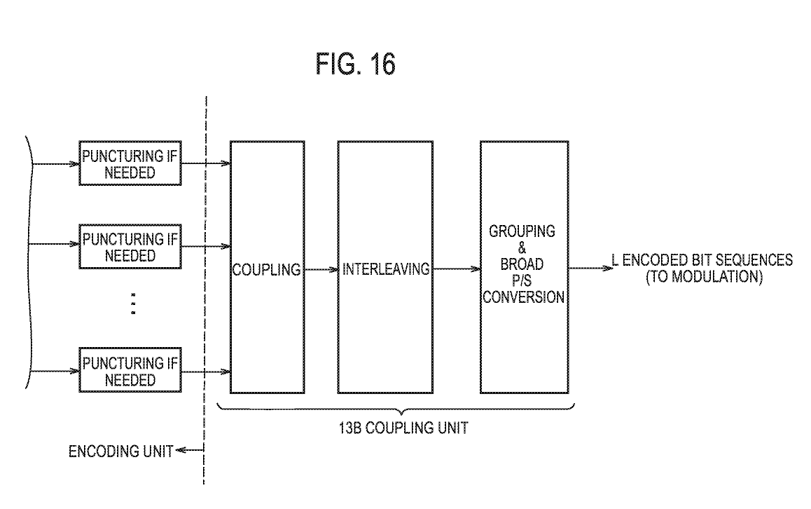

In the second embodiment, the encoding unit 12B of the transmitting side apparatus performs the interleaving, but the interleaving may be performed by the coupling unit 13B of the transmitting side apparatus as illustrated in FIG. 16.

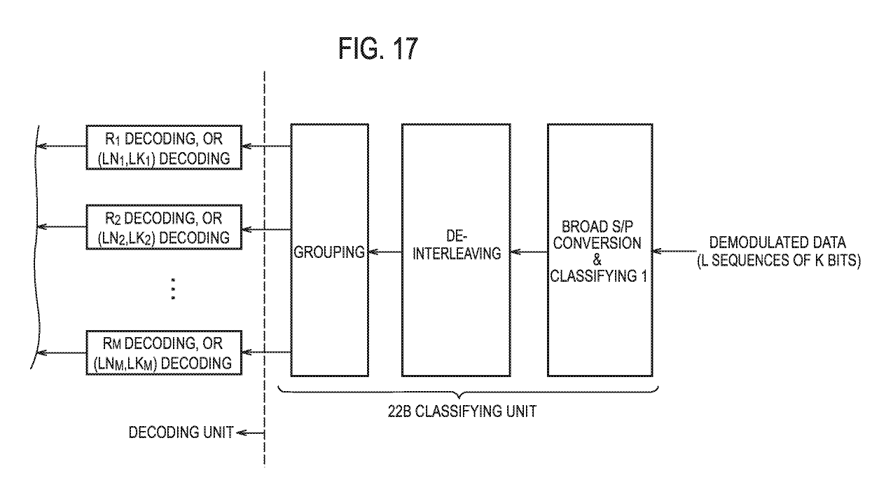

In the second embodiment, the decoding unit 23B of the receiving side apparatus performs the de-interleaving, but the de-interleaving may be performed by the classifying unit 22B of the receiving side apparatus as illustrated in FIG. 17.

### Second Modification of Second Embodiment

In the second embodiment, a method of setting “L” is not particularly mentioned, but, when each bit sequence (codeword) is equally grouped, an L is set so that LN/M is N (that is, L=M) as a basic form. However, LN/M may be N′ (N′>N) according to a design of the system. In the case of unequal grouping, LN1, . . . , LNM are set with no large deviation from N′ (it is possible even when N′=N or N′>N). By introducing N′, a setting can be performed so that N′>N, and system design flexibility can be obtained. For example, through equal grouping, it is possible to collect 768M N-bit (8-bit) data (that is, L=768M) and set N′=6144. Of course, a setting of LN/M=N (that is, L=M) can be performed by N=6144. In this case, since the input bit sequences are unlikely to be arranged in the order of from the MSB to the LSB, it is desirable to perform sorting once.

### Third Modification of Second Embodiment

In the second embodiment, a case in which an error is detected in the receiving side apparatus is not particularly mentioned, but the decoding unit 23B of the receiving side apparatus that has received the encoded bit sequence discards the received encoded bit sequence when an error is detected at the MSB side (the MSB group) in the received encoded bit sequence. Meanwhile, when an error is detected at the LSB side (the coupled encoded bit sequence corresponding to the LSB group), a predetermined value or an arbitrary value is inserted into the LSB side to make the received encoded bit sequence available. As a result, in the related art, when an error occurs, all information (the entire received encoded bit sequence) has to be discarded, but by allowing corruption of some information that is relatively unimportant, transmission efficiency of information can be improved.

### Other Embodiments

In the first and second embodiments, the MSB group is classified as the important group, and the LSB group is classified as the unimportant group, but the present disclosure is not limited to the MSB group and the LSB group and can be applied when parts having different degrees of importance are included in the information bit sequence.

In the above embodiment, the LTE system has been described as an example of the communication system, but the present disclosure is not limited to the LTE system and can be applied to a communication system other than the LTE system.

Priority is claimed on Japanese Patent Application No. 2013-252961, filed Dec. 6, 2013, the content of which is incorporated herein by reference.

### INDUSTRIAL APPLICABILITY

The present disclosure is useful in a radio communication field such as mobile communication.

1. A communication method comprising:
a grouping step of dividing information bit sequence to generate multiple information bit groups, in which a information bit group has degree of importance different from another information bit group;
an encoding step of individually encoding each of the multiple information bit groups at a coding rate corresponding to each of the degree of importance while maintaining a total coding rate for the multiple information bit groups to be a target coding rate;
a coupling step of coupling multiple encoded bit groups obtained by individually encoding the multiple information bit groups, to generate an encoded bit sequence; and
a transmitting step of transmitting the encoded bit sequence,
wherein, in the encoding step, the coding rate applied to a first information bit group having a higher degree of importance than a second information bit group, is lower than the coding rate applied to the second information bit group.

2. The communication method according to claim 1,
wherein the first information bit group includes a most significant bit (MSB) of the information bit sequence, and
the second information bit group includes a least significant bit (LSB) of the information bit sequence.

3. The communication method according to claim 1, further comprising:
a notification step of notifying, to another communication apparatus that receives the encoded bit sequence, content of a change in response to changing at least one of total number of the multiple information bit groups and number of bits of each of the multiple information bit groups.

4. The communication method according to claim 1,
wherein the grouping step comprises
a step of dividing each of multiple information bit sequences to generate multiple information bit groups having different degrees of importance for each information bit sequence, and
a step of coupling the information bit groups having same degree of importance to generate multiple coupled information bit sequences having different degrees of importance as a new information bit sequence,
the encoding step comprises a step of individually encoding each of the multiple coupled information bit sequences at a coding rates set according to a corresponding degree of importance while maintaining a total coding rate for the multiple coupled information bit sequences to be the target coding rate,
the coupling step comprises a step of coupling multiple coupled encoded bit sequences obtained by individually encoding the multiple coupled information bit sequences, and
in the encoding step, the coding rate applied to a first coupled information bit sequence of the multiple coupled information bit sequences having a higher degree of importance than a second coupled information bit sequence, is lower than the coding rate applied to the second coupled information bit sequence of the multiple coupled information bit sequences.

5. The communication method according to claim 4,
wherein the first coupled information bit sequence is a coupled information bit sequence obtained by coupling multiple information bit groups each of which includes a most significant bit (MSB) of information bit sequence, and
the second coupled information bit sequence is a coupled information bit sequence obtained by coupling multiple information bit groups each of which includes a least significant bit (LSB) of information bit sequence.

6. A communication method comprising:
a receiving step of receiving an encoded bit sequence obtained by encoding multiple information bit groups included in an information bit sequence, wherein each of the multiple information bit groups is individually encoded at a coding rate corresponding to each degree of importance while maintaining a total coding rate for the multiple information bit groups to be a target coding rate, and the coding rate applied to a first information bit group of the multiple bit groups having a higher degree of importance than a second information bit group, is lower than the coding rate applied to a second information bit group of the multiple bit groups;
a classifying step of dividing the encoded bit sequence to generate multiple encoded bit groups, in which a encoded bit group has degree of importance different from the other encoded bit group;
a decoding step of decoding each of the multiple encoded bit groups; and
a coupling step of coupling multiple information bit groups obtained by decoding the multiple encoded bit groups, to generate the information bit sequence.

7. The communication method according to claim 6,
wherein the first information bit group includes a most significant bit (MSB) of the information bit sequence, and
the second information bit group includes a least significant bit (LSB) of the information bit sequence.

8. The communication method according to claim 6, further comprising:
a step of receiving, from another communication apparatus that transmits the encoded bit sequence, a notification indicating content of a change in response to changing at least one of total number of the multiple information bit groups and number of bits of each of the multiple information bit groups.

9. The communication method according to claim 6,
wherein the classifying step comprises a step of classifying an encoded bit sequence obtained by coupling multiple coupled encoded bit sequences into the multiple coupled encoded bit sequences having different coding rates,
the decoding step comprises a step of decoding each of the multiple coupled encoded bit sequences,
the coupling step comprises
a step of classifying each of multiple coupled information bit sequences having different degrees of importance obtained by decoding the multiple coupled encoded bit sequences into multiple information bit groups, and
a step of coupling the information bit groups corresponding to each information bit sequence to generate multiple information bit sequences,
each of the multiple coupled information bit sequences is individually encoded at a coding rates set according to a corresponding degree of importance while maintaining a total coding rate for the multiple coupled information bit sequences to be the target coding rate, and
a coding rate of a first coupled information bit sequence of the multiple coupled information bit sequences having a higher degree of importance than a second coupled information bit sequence, is lower than the coding rate applied to the second coupled information bit sequence of the multiple coupled information bit sequences.

10. The communication method according to claim 9,
wherein the first coupled information bit sequence is a coupled information bit sequence obtained by coupling multiple information bit groups each of which includes a most significant bit (MSB) of information bit sequence, and
the second coupled information bit sequence is a coupled information bit sequence obtained by coupling multiple information bit groups each of which includes a least significant bit (LSB) of information bit sequence.

11. A communication apparatus comprising:
a processor configured to execute
a grouping process of dividing information bit sequence to generate multiple information bit groups, in which a information bit group has degree of importance different from another information bit group;
an encoding process of individually encoding each of the multiple information bit groups at a coding rate corresponding to each of the degree of importance while maintaining a total coding rate for the multiple information bit groups to be a target coding rate;
a coupling process of coupling multiple encoded bit groups obtained by individually encoding the multiple information bit groups, to generate an encoded bit sequence; and
a transmitting process of transmitting the encoded bit sequence,
wherein, in the encoding process, the coding rate applied to a first information bit group having a higher degree of importance than a second information bit group, is lower than the coding rate applied to the second information bit group.

12. A communication apparatus comprising:
a processor configured to execute
a receiving process of receiving an encoded bit sequence obtained by encoding multiple information bit groups included in an information bit sequence, wherein each of the multiple information bit groups is individually encoded at a coding rate corresponding to each degree of importance while maintaining a total coding rate for the multiple information bit groups to be a target coding rate, and the coding rate applied to a first information bit group of the multiple bit groups having a higher degree of importance than a second information bit group, is lower than the coding rate applied to a second information bit group of the multiple bit groups;
a classifying process of dividing the encoded bit sequence to generate multiple encoded bit groups, in which a encoded bit group has degree of importance different from other encoded bit group;
a decoding process of decoding each of the multiple encoded bit groups; and
a coupling process of coupling multiple information bit groups obtained by decoding the multiple encoded bit groups, to generate the information bit sequence.
